(19) United States
(12) Patent Application Publication
(10) Pub. No.: US 2017/0133529 A1
(43) Pub. Date: May 11, 2017

(54) PHOTOVOLTAIC MODULES AND METHOD OF MANUFACTURING A PHOTOVOLTAIC MODULE

(71) Applicant: SolarWorld Industries Sachsen GmbH, Freiberg (DE)

(72) Inventor: Rainer Thiel, Dresden (DE)

(21) Appl. No.: 14/933,119

(22) Filed: Nov. 5, 2015

(51) Int. Cl. H01L 31/048; H01L 31/18

(52) U.S. Cl. CPC H01L 31/048; H01L 31/1864

(57) ABSTRACT

In various embodiments, a photovoltaic module may include a photovoltaic laminate that includes a transparent front sheet and a rear side cover, one or more solar cells embedded in a embedding material arranged between the transparent front sheet and the rear side cover, and at least one frame profile arranged at one edge of the photovoltaic laminate, wherein at least a portion of the at least one frame profile is adhesively bonded to a portion of the embedding material.

### TECHNICAL FIELD

Various embodiments relate generally to photovoltaic modules and a method of manufacturing a photovoltaic module.

### BACKGROUND

Photovoltaic modules and solar cell modules are formed by laminating at least one solar cell between a front sheet and a rear side cover, further denoted as laminated module or module. Further, the manufacturing includes an applying of a frame at the edges of the laminated module. The frame usually works as a holding device that allows a mounting of the framed module in a mounting provision.

Thus, the manufacturing of a framed photovoltaic module, laminates having a frame or mounting devices, usually requires an adhesive bonding of the frame to the module usually using silicone or double sided tape. Both variants are realized after finish of lamination process. Conventionally, a silicone is applied between a U-shaped frame profile and a laminated module, e.g. by an injection of a silicone mold into the interspace between the frame and the laminated module. Then, the silicone is dried, that is solidified, wherein it is adhesively bonding the frame to the module. However, the framed module should not be handled, e.g. transported, as long as the silicone dries. However, a transport of the framed module to the next process stations, e.g. an additional machine, is usually necessary for proceeding with manufacturing. Thus, the conventional process of framing a module interrupts the process flow, e.g. depending on the drying time of the used silicone, and, thus, prolongs the manufacturing process for photovoltaic modules and solar cell modules.

Furthermore, in building and construction industry, stainless steel elements are usually laminated between multilayer glass plates using an embedding material, e.g. SentryGlas by DuPont, to mount the heavy-weighted composite glass plates at a building facade.

### SUMMARY

In various embodiments, a photovoltaic module may include a photovoltaic laminate that includes a transparent front sheet and a rear side cover. One or more solar cells may be embedded in an embedding material arranged between the transparent front sheet and the rear side cover. At least one frame profile may be arranged at one edge of the photovoltaic laminate. At least a portion of the at least one frame profile may adhesively bonded to a portion of the embedding material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows in a schematic representation a cross sectional view of a framed module according to various embodiments;

FIGS. 2 shows in a schematic representation a cross sectional view of a framed module according to various embodiments;

FIG. 3 shows in a schematic representation a cross sectional view of a framed module according to various embodiments;

FIG. 4 shows in a schematic representation a cross sectional view of a framed module according to various embodiments;

FIG. 5 shows in a schematic representation a cross sectional view of a framed module according to various embodiments;

FIG. 6 shows in a schematic representation a top view of a framed module according to various embodiments;

FIG. 7 shows a diagram illustrating a method for manufacturing a module according to various embodiments;

FIG. 8 shows in a schematic representation a cross sectional view of a framed module according to various embodiments;

FIG. 9 shows in a schematic representation a cross sectional view of a framed module according to various embodiments; and

FIG. 10 shows in a schematic representation a cross sectional view of a framed module according to various embodiments.

### DESCRIPTION

The following detailed description refers to the accompanying drawings that show, by way of illustration, specific details and embodiments in which various embodiments may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

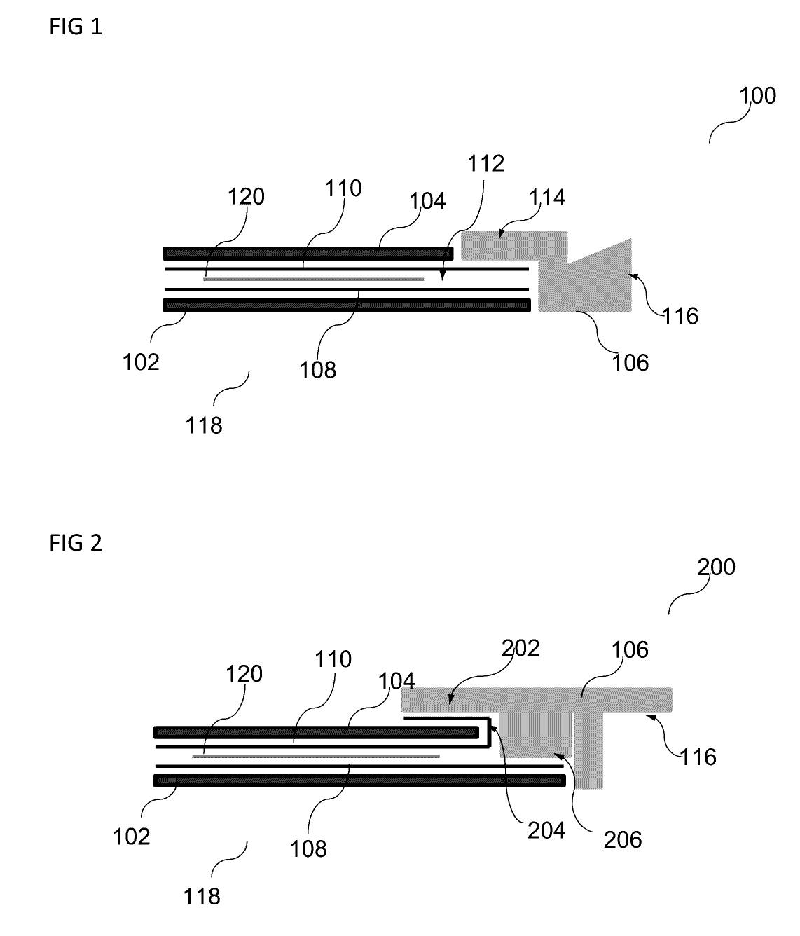

FIG. 1 shows, in a schematic representation, a cross sectional view of a framed module 100 according to various embodiments. The module may be a solar cell module or a photovoltaic module.

The photovoltaic module 100 may include a photovoltaic laminate having one or more solar cells 120 between a transparent front sheet 102 and a rear side cover 104. The transparent front sheet 102 may be arranged on that side of the module 100 that is exposed to the electromagnetic radiation 118 that is transformed into an electrical energy in the one or more cells 120. The one or more solar cells 120 may be arranged between the transparent front sheet 102 and the rear side cover 104, e.g. in a cavity between formed in the interspace 112 between the transparent front sheet 102 and the rear side cover 104.

In various embodiments, a layer may be arranged between the embedding material 108, 110 and the rear side cover and/or between the embedding material 108, 110 and the transparent front sheet 102. At least a portion of the at least one frame profile may be adhesively bonded to a portion of the layer.

In various embodiments, the layer and the embedding material may be formed from the same material. In various embodiments, the embedding material may be transparent or dyed, e.g. white.

In various embodiments, the layer may include a hot melt adhesive.

The one or more solar cells 120 may be embedded in an embedding material 108, 110. At least one frame profile (partially shown in FIG. 1) 106 may be attached to the photovoltaic laminate. However, FIG. 1 only shows a portion of one frame profile 106 at the edge of the photovoltaic laminate of the framed module 100. At least a portion of the at least one frame profile 106 may be adhesively bonded to a material partially arranged between the transparent front sheet 102 and the rear side cover 104, e.g. to the embedding material 108, 110, as will be described in more detail below.

Subsequently, the structure having the transparent front sheet 102 or the front side cover 102, respectively, the rear side cover 104 and the one or more solar cells 120 are referred to as a laminate, when they are laminated together, e.g. by a lamination process carried out e.g. in a lamination oven. Thus, the module or framed module may include the laminate and the at least one frame profile that is adhesively bonded to the laminate.

In various embodiments, the embedding material 108, 110 may include or may be formed by a first embedding sheet 108 and a second embedding sheet 110. However, it is also possible that the embedding material includes only the first embedding sheet 108 or only the second embedding sheet 110. The first embedding sheet 108 and the second embedding sheet 110 may be formed from the same or different materials.

The one or more solar cells 120 may be embedded in a cavity in the embedding material 108, 110. The cavity of the embedding material 108, 110 may be formed by the first embedding sheet 108 and the second embedding sheet 110. This structure may be arranged in the interspace 112 between the transparent front sheet 102 (also referred to e.g. as a transparent front side cover 102), and the rear side cover 104. The first embedding sheet 108 may be laminated to (and may be in physical contact to) the rear side cover 104 and the second embedding sheet 110 may be laminated to (and may be in physical contact to) the transparent front side cover 102.

The transparent front sheet 102 and the rear side cover 104 may be adhesively bonded to the one or more solar cells 120, e.g. by the first embedding sheet 108 and the second embedding sheet 110. The adhesive bonding may be formed in a subsequent lamination process, as will be described in more detail below.

The front side cover 102 may be a glass or a foil. Furthermore, the rear side cover 104 may be a glass or a foil.

In various embodiments, the embedding material, e.g. formed by the first embedding sheet 108 and the second embedding sheet 110, may be the material partially arranged between the transparent front side cover 102 and the rear side cover 104 to adhesively bond the portion of the at least one frame profile 106.

In various embodiments, the embedding material, e.g. the first embedding sheet 108 and the second embedding sheet 110, may include a hot melt adhesive, e.g. an ethylene-vinyl acetat (EVA), also known as poly(ethylene-vinyl acetat) (PEVA). The embedding material, e.g. the first embedding sheet 108 and the second embedding sheet 110, for example combined, may be thick enough to embed the one or more solar cells and to form a reliably lasting bond between the at least one frame profile 106 and the laminate.

Thus, an additional adhesive bonding of the at least one frame profile 106 to the laminate using a silicone, may be omitted or becomes optional. Further, a mechanical load can be applied to the framed module 100, e.g. during a transport of the framed module 100, directly after the lamination process and, thus, reduces the production time of the framed module. Further, the silicone conventionally used as adhesive and the application device for applying the silicone can be omitted and, thus, the production and maintenance costs may be reduced.

As further shown in FIG. 1, in various embodiments, the rear side cover 104 may have a smaller width than the transparent front sheet 102. Thus, at least a portion 114 of the embedding material 108, 110 may be laterally exposed. The at least one frame profile 106 may be adhesively bonded to the exposed portion of the embedding material on the transparent front sheet. Thus, the adhesively bonded portion 114 of the at least one frame profile 106 may be adhesively bonded to at least a part of the laterally exposed embedding material 108, 110, e.g. (only) to the transparent first embedding sheet 108, or (only) to the transparent second embedding sheet 110 or to the transparent first embedding sheet 108 and the transparent second embedding sheet 110.

Alternatively, the front sheet 102 or front side cover 102 may have a smaller width than the rear side cover 104.

The smaller width may be at least a long side, all long sides or on all sides of the rear side cover 104 or the transparent front sheet 102, respectively.

The difference between the width of the rear side cover 104 and the transparent front sheet 102 may be in a range from about a few mm to about a few cm. The smaller width of the transparent front sheet 102 or rear side cover 104 having the smaller width respectively may be formed before or after assembling the laminate.

In various embodiments, the at least one frame profile 106 may be adhesively bonded only to or via the first embedding sheet 108. Alternatively, the second embedding sheet 110 may be laminated to the transparent front sheet 102, and the at least one frame profile 106 may adhesively bonded to or via the first embedding sheet 108 and to the second embedding sheet 110. Further alternatively, the at least one frame profile 106 are adhesively bonded to different embedding sheets.

As further shown in FIG. 1, at least one frame profile 106 may include a holding section 116, e.g. a regarding the light active surface laterally extending portion in a trapezoidal-, triangular-, truncated cone-shape and further in a dove tail- or cubic-shape as shown below, at an outer side of the frame profile 106. The holding section 116 may enable a mounting of the framed module 100 in a holding device (not shown), e.g. for mounting in a form-fitting or force-locking manner, e.g. clamping.

In various embodiments, the at least one frame profile 106 may be formed and bonded to the laminate such that it partially extends to a side sheet 102 or rear side cover 104 of the laminate facing away from the embedding material 108, 110. In other words: the at least one frame profile may be bonded to the laminate such that it substantially does not extend beyond an outer surface of the transparent front sheet 102 or rear side cover 104. The extending portion may be a portion, as an example, of a holding section of the frame profiles.

Alternatively or in addition, at least one frame profile 106 may be formed and bonded to the laminate such that the frame profile 106 substantially does not extend further to a side of the laminate than the surface of the front side sheet 102 or front side cover 102, or rear side cover 104 facing away from the embedding material 108, 110, see e.g. FIG. 1, FIG. 4 or FIG. 5. This way, the laminate and the at least one frame profile may be arranged and laminated on a flat surface in a lamination device, e.g. a plain hot plate of an oven, in a simple manner.

In various embodiments, at least one frame profile 106 may be, for example, an (e.g. anodized) aluminium profile, e.g. formed by an extrusion.

FIG. 2 shows in a schematic representation a cross sectional view of a framed module 200 according to various embodiments. The module 200 may be substantially similar to the various embodiments as described above. In addition, for example, as further shown in FIG. 2, the at least one frame profile 106 may be adhesively bonded to the second embedding sheet 110 and to a narrow side 204 of the laminate. Further, an embedding sheet, e.g. the second embedding sheet 110 as illustrated in FIG. 2, may be bent at the narrow side 204 of the laminate. The bend portion of the embedding sheet may be bent towards the rear side surface of the rear side cover 104. This way, embedding material may be provided on the back and/or on a narrow side 204 of the laminate 200. This way, at least one frame profile 106 may be adhesively bonded to the rear side surface of the laminate via the bent embedding material, e.g. second embedding sheet 110. Thus, at least one frame profile 106 may be adhesively bonded to only one of the first embedding sheet 108 or the second embedding sheet 110 of the embedding material. However, the embedding material may be formed as first 108 and second embedding sheets 110 only in the exposed portion of the embedding material. The embedding material may be coherent in the interspace between the transparent front sheet 102 and the rear side cover 104 but having a cavity embedding the one or more solar cells 120.

Alternatively or in addition, at least one frame profile 106 may be adhesively bonded to the transparent front sheet 102 via the embedding, e.g. the first embedding sheet 108. This may form a more reliably lasting mechanical connection between the at least one frame profile 106 and the laminate.

In a further aspect, each frame profile of the at least one frame profile 106 may have a stepped shape. This way, a surface of a first step 202 of a frame profile 106 may be adhesively bonded the embedding material on the rear side cover 104, and that a surface of a second step 206 of the frame profile 106 may be adhesively bonded to the embedding material on the transparent front sheet 102.

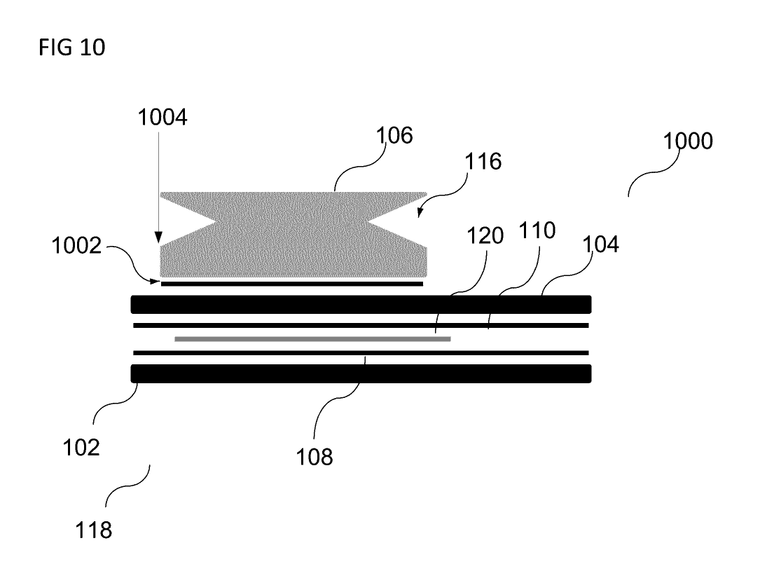

In various embodiments, the at least one frame profile 106 may include an adhesive layer (see also FIG. 10), e.g. formed from a hot melt adhesive. The adhesive layer may be attached, for example, at the first step 202, the narrow side 204 and/or the second step 206. This way, the at least one frame profile may be adhesively bonded at the edge of the laminate via the exposed portion of the embedding material 108, 110, the adhesive layer or the embedding material 108, 110 and the adhesive layer. Further, the adhesive layer may be arranged partially between the front sheet 102 and rear side cover 104. Moreover, the adhesive layer may be or form a part of the embedding material 108, 110. As an example, the adhesive layer may partly or completely form the exposed portion of the embedding material 108, 110 that is used to adhesively bond the at least one frame profile to the laminate.

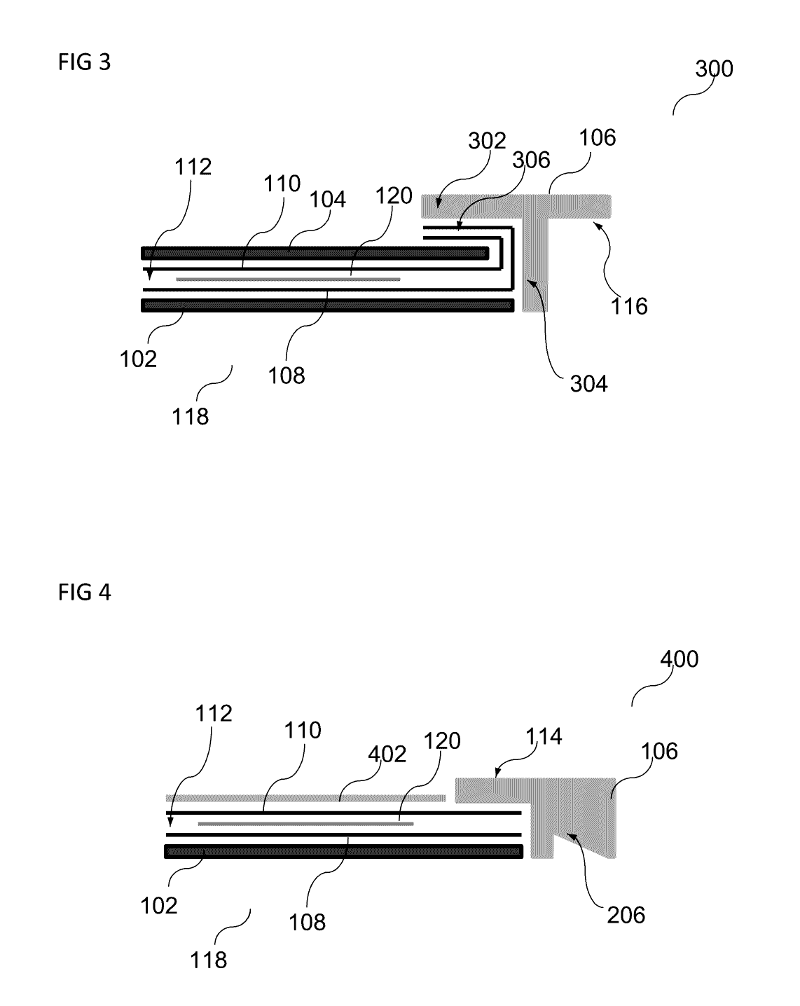

FIG. 3 shows in a schematic representation a cross sectional view of a framed module 300 according to various embodiments. The framed module 300 may be substantially similar to the various embodiments as described above. In addition, for example, as further shown in FIG. 3, in a further aspect, the at least one frame profile 106 may have an angular shape. In other words, of the at least one frame profile 106 may have a first leg 302 and a second leg 304 extending substantially at an angle from the first leg 302, e.g., about 90°.

In various embodiments, one leg of the at least one frame profile may be adhesively bonded to a rear side surface 306 of the laminate. The other leg of the at least one frame profile may be adhesively bonded to a narrow side of the photovoltaic.

In various embodiments, a first leg 302 of the at least one frame profile 106 may be adhesively bonded to a rear side surface 306 of the laminate, e.g. to a rear side surface of the rear side cover 104, and a second leg 304 of the at least one frame profile 106 may be adhesively bonded to a narrow side of the laminate. The second leg 304 of the at least one frame profile may run in an angle to, e.g. perpendicular to the first leg of the at least one frame profile.

Further shown in FIG. 3, in various embodiments, the front side sheet 102 and the rear side cover 104 may have the same or substantially same width.

Thus, the embedding material 108, 110, e.g. the first embedding sheet 108, the second embedding sheet 110 or the first embedding sheet 108 and the second embedding sheet 110, may have a width larger than the front side sheet 102 and/or rear side cover 104.

Thus, as shown in FIG. 3, a portion of the first embedding sheet 108, the second embedding sheet 110 or the first embedding sheet 108 and the second embedding sheet 110 having a width larger than the front side sheet 102 or front side cover 102, or rear side cover 104 is/are bent at a narrow side of the laminate and, optionally in addition, onto a surface of the front side sheet 102 or front side cover 102, or the rear side cover 104. Here, at least one frame profile 106 may be adhesively bonded at the narrow side, and if present, at the surface of the front side sheet 102 or front side cover 102, or rear side cover 104 via the embedding material, e.g. at least one of the first embedding sheet 108 and the second embedding sheet 110.

Alternatively, the front side sheet 102 or front side cover 102, and the rear side cover 104 may have the same or substantially same width but are laterally shifted regarding each other. This way, a first frame profile 106 may be adhesively bonded to the laminate via the first embedding sheet 108 and a second frame profile 106 may be adhesively bonded to the laminate via the second embedding sheet 110. Hence, a first frame profile having an angular shape, e.g. as shown in FIG. 3 as described above, may be adhesively bonded to the front side sheet 102 via its first leg 302, and a second frame profile having an angular shape may be adhesively bonded to the rear side cover 104 via its first leg 302 wherein the second leg may be located at the narrow side for both first and second frame profiles.

FIG. 4 shows in a schematic representation a cross sectional view of a framed module according to various embodiments. The module 400 may be substantially similar to various embodiments as described above. In addition, for example, as further shown in FIG. 4 to FIG. 6, in various embodiments, the at least one frame profile 106 may be bonded to the laminate such that it substantially does not extend further to a side of the laminate than the surface of the transparent front sheet 102 or transparent front cover 102, or rear side cover 104 facing away from the embedding material 108, 110. As shown for example in FIG. 4, the frame profiles may not substantially extend further to a rear side of the laminate although having a holding section. Furthermore, as shown in FIG. 4, the rear side cover 402 may be formed as a foil and the front side cover 102 or front side sheet 102 may be formed as a glass.

In various embodiments, the rear side cover 104 and the front sheet 102 may have substantially the same physical dimension, e.g. formed and aligned having a congruent coverage.

FIG. 5 shows in a schematic representation a cross sectional view of a framed module 500 according to various embodiments. The framed module 500 may be substantially similar to various embodiments as described above. In addition, for example, as further shown in FIG. 5, in a further aspect, the transparent front sheet 102 and the rear side cover 104 may have a similar width and at least one frame profile 106 may be adhesively bonded between transparent front sheet 102 and the rear side cover 104 via the embedding material. In other words: a portion of at least one frame profile may be arranged in the interspace between the transparent front sheet 102 and the rear side cover 104. The portion of at least one frame profile in the interspace 112 may be embedded in the embedding material, e.g. between the first 108 and second embedding sheets 110. This way, the laminate and the frame profile may be assembled in simple manner, e.g. regarding a subsequent lamination process.

Further, as shown in for example in FIG. 5, the frame profiles may not substantially extend further to a rear side and front side of the laminate although having a holding section 502. Further shown in FIG. 5, the rear side cover 104 and the front side cover 102 or front side sheet 102 may be formed as a glass.

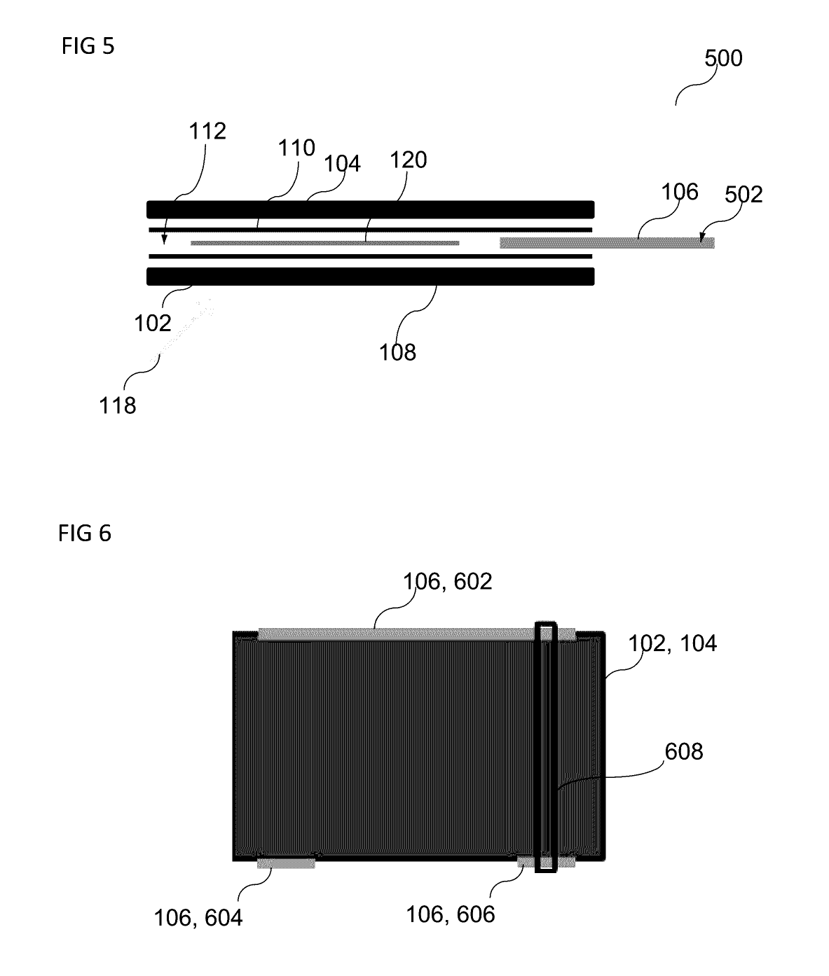

FIG. 6 shows in a schematic representation a top view of a framed module 600 according to various embodiments. The framed module 600 may be substantially similar to various embodiments as described above. In addition, for example, as further shown in FIG. 6, in various embodiments, two or more frame profiles 106, e.g. a first frame profile 106, 602, a second frame profile 106, 604 and a third frame profile 106, 606, may be arranged at opposite sides of the photovoltaic laminate.

Further, during production of the module, the assembled laminate and at least one profile 106, 602, 604, 606 may be fixated in the assembled position by a fixating provision 608 during lamination. The fixating provision 608 may be, for example, a clasp, a buckle, a strap or a brace.

The fixating provision 608 may be reversibly attachable to the laminate and frame profile(s) for fixating their relative position.

The fixating provision 608 may be formed or include a thin metal. Thus, good heat dissipation may be enabled in the fixating provision 608 during the lamination process, e.g. a thermocompression process.

The fixating provision 608, shown in an example in FIG. 6, may fixate the position of at least one frame profile 106, 602, 604, 606 in a form-fitting or lock-fitting manner regarding the position of the laminate during the lamination process. In FIG. 6, a fixating provision 608 is shown that fixates the first frame profile 602 and the third frame profile 606 that are arranged at opposing sides of the laminate. This way, one fixating provision 608 may be used for fixating two or more frame profiles 106, 602, 604, 606 at a time.

After the lamination process, the fixating provision 608 may be removed from the framed module 600.

The first 602, second 604 and third 606 frame profiles may be equal or different from each other. The first frame profile 602 shown in FIG. 6 may have a larger length than the second 604 and third frame profiles 606, respectively. The second frame profile 604 and the third frame profile 606 may have an equal or substantially equal length.

In various embodiments, as shown for example in FIG. 6, the first frame profile 602 is formed, e.g. may have a length, to extend along a substantially whole first side of the laminate. This way, when mounting the framed module using the holding section of at least one frame profile for mounting in a mounting device, the mechanical load may be dissipated substantially homogenous along the first side. Further, alternatively or in addition, a second 604 and a third frame profile 606 may have a length that is substantially smaller than a second side of the laminate, which for example may be on the opposing side of the first side, and may be arranged at the second side.

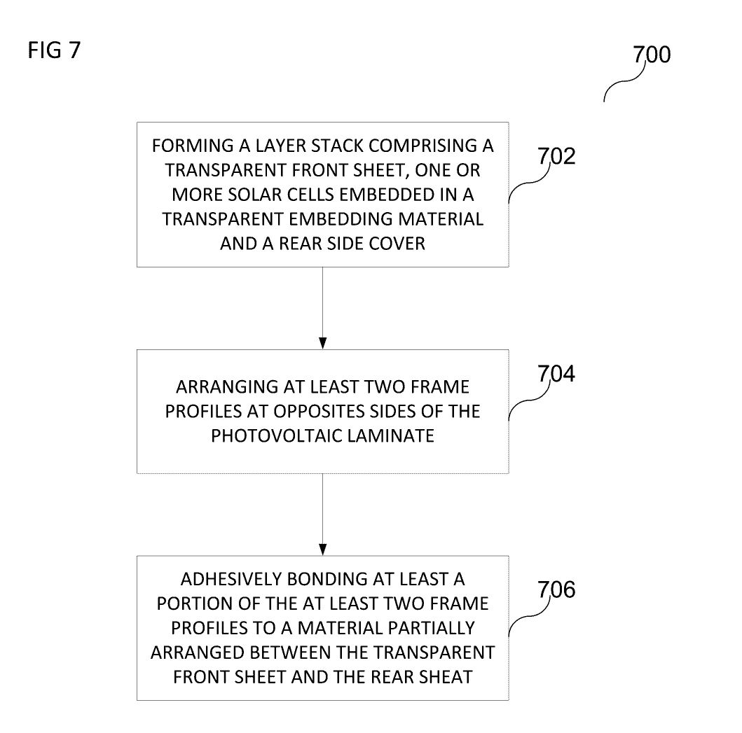

FIG. 7 shows a diagram illustrating a method 700 for manufacturing a module according to various embodiments. The method 700 includes a forming 702 of a layer stack. The layer stack includes a transparent front sheet, a first and a second embedding sheet with one or more solar cells enclosed and a rear side cover, e.g. as described above.

A portion of first or second embedding sheet may remain exposed at one edge of the layer stack. Further, a portion of first or second embedding sheet may remain exposed at two opposite sides of the layer stack.

The first and second embedding sheets may include or may be formed from a hot melt adhesive. The first and second embedding sheets may have, for example, the shape of a sheet, foil or plate.

Thus, a first embedding sheet may be arranged on the front side sheet, the at least one solar cell may be arranged on the first embedding sheet, the second embedding sheet may be arranged on the at least one solar cell and, thus, on and above the first embedding sheet, and, then, the rear side cover is arranged on the second embedding sheet, and, this way, forming the assembled laminate.

The method 700 may further include arranging 704 of at least one frame profile on the exposed portion. At least one frame profile may be reversibly fixated at the laminate using a fixating provision, e.g. as described above. This way, the position of the fixated at least one frame profile is fixated regarding the laminate during the transport to the lamination device, e.g. into an oven, and, further, during the lamination process.

The method 700 may further include adhesively bonding 706 the layer stack that may include the at least one frame profile to form a photovoltaic module.

The adhesively bonding 706 may be a lamination process using heat, pressure or heat and pressure, e.g. a thermocompression bonding. The heat may lead to a melting of the embedding material. The melting of the embedding material having a first and a second embedding sheet may lead to a merging of the first and second embedding sheets into a substantially coherent embedding material having a cavity that includes the at least one solar cell. This way, the at least one solar cell may be embedded in the embedding material.

Further, the embedding material may be the material to adhesively bond the at least one frame profile to the laminate.

Hence, the melting of the embedding material may cause, on the one hand, an embedding of the solar cell in the embedding material and, on the other hand, may cause an adhesively bonding of the at least one frame profile to the laminate. This way, the embedding material according to various embodiments may act as embedding material and adhesive conventionally used.

The embedding material according to various embodiments may have a thickness larger than the conventional embedding material since the embedding material according to various embodiments also acts as an adhesive and should form a reliably lasting bond. However, depending on the cohesion and density of the used embedding material, the thickness of the embedding material may be equal to or smaller than the thickness of the embedding material used in the prior art, e.g. in case an embedding material is used that has a larger cohesion than one conventionally used for lamination.

Further, regarding the lamination process, the width of the laminate with the at least one frame profile can be small enough to further use existing lamination devices, e.g. ovens. This way, the lamination devices and size of the modules can remain substantially unchanged.

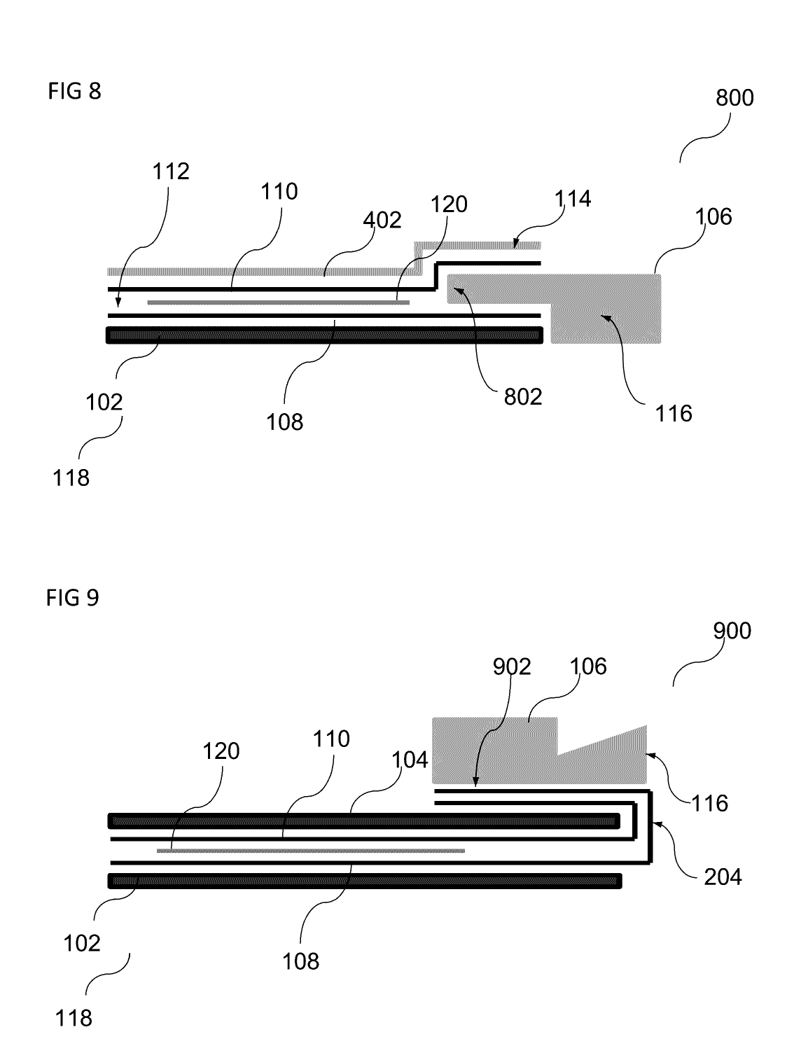

FIG. 8 shows in a schematic representation a cross sectional view of a framed module according to various embodiments. The module 800 may be substantially similar to various embodiments as described above. In addition, for example, as further shown in FIG. 8 and as shown in FIG. 4, the rear side cover 402 may be formed as a foil and the front side cover 102 or front side sheet 102 may be formed as a glass. The rear side cover 402 may be mechanically flexible and may cover or follow the contour or elevation profile (illustrated in FIG. 8 as a step 802) of at least the portion of the at least one frame profile 106 that is partially embedded in the embedding material 108, 110 between the front side sheet 102 and the rear side cover 402. Thus, the rear side cover 402 may form a smooth surface of the laminate substantially without a step or gap in the rear side surface. Hence, the rear side of the laminate may have an appearance of higher quality. Even further, this way, the holding section 116 of the at least one frame profile may have shape of a pin or tap.

FIG. 9 shows in a schematic representation a cross sectional view of a framed module according to various embodiments. The module 900 may be substantially similar to various embodiments as described above. In addition, for example, as further shown in FIG. 9 and as shown in FIG. 4, in various embodiments, the front side sheet 102 and the rear side cover 104 may have the same or substantially same width wherein the embedding material 108, 110 may have a width larger than the front side sheet 102 and/or rear side cover 104.

Thus, as shown in FIG. 9, a portion of the first embedding sheet 108 and the second embedding sheet 110 having a width larger than the front side sheet 102 and the rear side cover 104 may be bent at a narrow side 204 of the laminate and onto a surface of, for example, the rear side cover 104. Here, the at least one frame profile 106 may be adhesively bonded to the rear side surface of the rear side cover 104 via the portion 902 of the embedding material 108, 110 at the rear side surface of the rear side cover 104.

FIG. 10 shows in a schematic representation a cross sectional view of a framed module according to various embodiments. The module 1000 may be substantially similar to various embodiments as described above. In addition, for example, as further shown in FIG. 10, the at least one frame profile may be adhesively bonded at one edge of the laminate via an adhesive layer 1002 that may be attached to the at least one frame profile 106. Further, in various embodiments, the at least one frame profile 106 may be attached to the one edge of the laminate, e.g. the rear side surface of the rear side cover 104 or the exposed portion of the embedding material such that the frame profile does not protrude the laminate laterally (illustrated in FIG. 10 via arrow 1004). Hence, the holding sections 116 of the modules 110 may be arranged at the optically inactive rear side of the module 1000. This way, the optically inactive region of a photovoltaic module 1000 may be reduced since. Thus, the packaging density of a photovoltaic installation having a plurality of such photovoltaic modules may be increased and, thus, its performance may be increased. Further, a modules 1000 substantially without a visible, optically inactive holding section 116 may have an appearance of higher quality.

In various embodiments, a photovoltaic module may be provided. The photovoltaic module may include a photovoltaic laminate and at least one frame profile arranged at one edge of the photovoltaic laminate. The photovoltaic module may include a transparent front sheet and a rear side cover, one or more solar cells embedded in an embedding material arranged between the transparent front sheet and the rear side cover. At least a portion of the at least one frame profile may be adhesively bonded to a portion of the embedding material.

In various embodiments, the rear side cover has a smaller width than the transparent front sheet to laterally expose at least a portion of the embedding material and wherein the at least one frame profile is adhesively bonded to the exposed portion of the embedding material on the transparent front sheet.

In various embodiments, the rear side cover may be a glass or a foil.

In various embodiments, the at least one frame profile may have a stepped shape so that a surface of a first step may be adhesively bonded to the embedding material on the rear side cover and that a surface of a second step may be adhesively bonded to the embedding material on the transparent front sheet.

In various embodiments, the at least one frame profile may be adhesively bonded to the embedding material provided on the back and the narrow side of the photovoltaic laminate.

In various embodiments, the at least one frame profile may be bonded to the photovoltaic laminate such that it substantially does not extend beyond an outer surface of the transparent front sheet.

In various embodiments, the at least one frame profile may have a first leg and a second leg extending substantially at an angle from the first leg, e.g. about 90°. One leg of the at least one frame profile may be adhesively bonded to a rear side surface of the photovoltaic laminate. The other leg of the at least one frame profile may be adhesively bonded to a narrow side of the photovoltaic laminate.

In various embodiments, the at least one frame profile may include a portion which is embedded in the embedding material arranged between the transparent front sheet and the rear side cover along one edge of the photovoltaic laminate. The rear side cover may have substantially a same size as the transparent front sheet.

In various embodiments, a photovoltaic module is provided. The photovoltaic module may include a transparent front sheet and a rear side cover. Further, one or more solar cells may be embedded in an embedding material arranged between the transparent front sheet and the rear side cover. A layer may be arranged between the embedding material and the rear side cover. At least one frame profile may be arranged at one edge of the photovoltaic laminate. At least a portion of the at least one frame profile may be adhesively bonded to a portion of the layer.

In various embodiments, the layer and the embedding material may be formed from the same material.

In various embodiments, a photovoltaic module is provided. The photovoltaic module may include a photovoltaic laminate having a transparent front sheet and a rear side cover, one or more solar cells embedded in an embedding material arranged between the transparent front sheet and the rear side cover and at least one frame profile arranged on the rear side cover and adhesively bonded to the rear side cover via an adhesive layer. The adhesive layer and the embedding material consist of the same material.

In various embodiments, a method of manufacturing a photovoltaic module is provided. The method may include a forming of a layer stack. The layer stack may include a transparent front sheet, a first and a second embedding sheet with one or more solar cells enclosed and a rear side cover. A portion of the first or second embedding sheet may remain exposed at one edge of the layer stack. The method further includes an arranging the at least one frame profile on the exposed portion. Further, the method may include an adhesively bonding of the layer stack including the at least one frame profile to form a photovoltaic module.

In various embodiments, the adhesively bonding may include laminating the layer stack together with the at least one frame profile using heat and pressure.

In various embodiments, the rear side cover may have a smaller width than the transparent front sheet to laterally expose at least a portion of the first and/or the second embedding sheet, which is the first embedding sheet, the second embedding sheet or the first embedding sheet and the second embedding sheet.

In various embodiments, the rear side cover may be a glass or a foil.

In various embodiments, at least one of the first and second embedding sheets may include the embedding material.

In various embodiments, the at least one frame profile may be adhesively bonded to the first embedding sheet and to the second embedding sheet.

In various embodiments, the at least one frame profile may have a stepped shape so that a surface of a first step may be adhesively bonded to the first embedding sheet and that a surface of a second step may be adhesively bonded to the second embedding sheet.

In various embodiments, the at least one frame profile may be adhesively bonded to the second embedding sheet and to a narrow side of the photovoltaic laminate.

In various embodiments, the at least one frame profile may be bonded to the photovoltaic laminate such that it substantially does not extend beyond an outer surface of the transparent front sheet.

In various embodiments, the at least one frame profile may have a first leg and a second leg extending substantially at an angle from the first leg. One leg of the at least one frame profile may be adhesively bonded to a rear side surface of the photovoltaic laminate. The other leg of the at least one frame profile may be adhesively bonded to a narrow side of the photovoltaic laminate.

By means of various embodiments, an additional adhesive bonding of the at least one frame profile to the laminate using a silicone, may be omitted or becomes optional. Further, a mechanical load can be applied to the framed module, e.g. during a transport of the framed module, directly after the lamination process and, thus, reduces the production time of the framed module. Further, the silicone conventionally used as adhesive and the application device for applying the silicone can be omitted and, thus, the production and maintenance costs may be reduced.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photovoltaic module, comprising:
a photovoltaic laminate, comprising:
a transparent front sheet and a rear side cover;
one or more solar cells embedded in an embedding material arranged between the transparent front sheet and the rear side cover; and
at least one frame profile arranged at one edge of the photovoltaic laminate;
wherein at least a portion of the at least one frame profile is adhesively bonded to a portion of the embedding material.

2. The photovoltaic module of claim 1,
wherein the rear side cover has a smaller width than the transparent front sheet to laterally expose at least a portion of the embedding material and wherein the at least one frame profile is adhesively bonded to the exposed portion of the embedding material on the transparent front sheet.

3. The photovoltaic module of claim 1,
wherein the rear side cover is a glass or a foil.

4. The photovoltaic module of claim 1,
wherein the at least one frame profile has a stepped shape so that a surface of a first step is adhesively bonded to the embedding material on the rear side cover and that a surface of a second step is adhesively bonded to the transparent embedding material on the transparent front sheet.

5. The photovoltaic module of claim 1,
wherein the at least one frame profile is adhesively bonded to the embedding material provided on the back and the narrow side of the photovoltaic laminate.

6. The photovoltaic module of claim 1,
wherein the at least one frame profile is bonded to the photovoltaic laminate such that it substantially does not extend beyond an outer surface of the transparent front sheet.

7. The photovoltaic module of claim 1,
wherein the at least one frame profile has a first leg and a second leg extending substantially at an angle from the first leg;
wherein one leg of the at least one frame profile is adhesively bonded to a rear side surface of the photovoltaic laminate; and
wherein the other leg of the at least one frame profile is adhesively bonded to a narrow side of the photovoltaic laminate.

8. The photovoltaic module of claim 1,
wherein the at least one frame profile comprises a portion which is embedded in the embedding material arranged between the transparent front sheet and the rear side cover along one edge of the photovoltaic laminate and
wherein the rear side cover has substantially a same size as the transparent front sheet.

9. A photovoltaic module, comprising:
a transparent front sheet and a rear side cover;
one or more solar cells embedded in an embedding material arranged between the transparent front sheet and the rear side cover; and
a layer arranged between the embedding material and the rear side cover;
at least two frame profiles arranged at opposite sides of the photovoltaic laminate;
wherein at least a portion of the at least one frame profile is adhesively bonded to a portion of the layer.

10. The photovoltaic module of claim 9,
wherein the layer and the embedding material are formed from the same material.

11. A photovoltaic module, comprising:
a photovoltaic laminate, comprising:
a transparent front sheet and a rear side cover;
one or more solar cells embedded in an embedding material arranged between the transparent front sheet and the rear side cover; and
at least one frame profile arranged on the rear side cover and adhesively bonded to the rear side cover via an adhesive layer;
wherein the adhesive layer and the embedding material consist of the same material.

12. A method of manufacturing a photovoltaic module, the method comprising:
forming a layer stack, the layer stack comprising:
a transparent front sheet;
a first and a second embedding sheet with one or more solar cells enclosed;
a rear side cover;
wherein a portion of first or second embedding sheet remains exposed at one edge of the layer stack; and
arranging the at least one frame profile on the exposed portion; and
adhesively bonding the layer stack including the at least one frame profile to form a photovoltaic module.

13. The method of claim 12,
wherein the adhesively bonding comprises laminating the layer stack together with the at least one frame profile using heat and pressure.

14. The method of claim 12,
wherein the rear side cover has a smaller width than the transparent front sheet to laterally expose at least a portion of the first and/or the second embedding sheet.

15. The method of claim 12,
wherein the rear side cover is a glass or a foil.

16. The method of claim 12,
wherein at least one of the first and the second embedding sheets comprises the transparent embedding material.

17. The method of claim 12,
wherein the at least one frame profile is adhesively bonded to the first embedding sheet and to the second embedding sheet.

18. The method of claim 17,
wherein the at least one frame profile has a stepped shape so that a surface of a first step is adhesively bonded to the first embedding sheet and that a surface of a second step is adhesively bonded to the second embedding sheet.

19. The method of claim 12,
wherein the at least one frame profile is adhesively bonded to the second embedding sheet and to a narrow side of the photovoltaic laminate.

20. The method of claim 12,
wherein the at least one frame profile is bonded to the photovoltaic laminate such that it substantially does not extend beyond an outer surface of the transparent front sheet.

21. The method of claim 11,
wherein at least one frame profile has a first leg and a second leg extending substantially at an angle from the first leg;
wherein one leg of the at least one frame profile is adhesively bonded to a rear side surface of the photovoltaic laminate; and
wherein the other leg of the at least one frame profile is adhesively bonded to a narrow side of the photovoltaic laminate.
